(19) United States
(12) Patent Application Publication
(10) Pub. No.: US 2016/0353607 A1
(43) Pub. Date: Dec. 1, 2016

(54) ELECTRONIC EQUIPMENT AND HEAT RECEIVING DEVICE

(71) Applicant: FUJITSU LIMITED, Kawasaki-shi (JP)

(72) Inventor: Jun TAGUCHI, Miura (JP)

(73) Assignee: FUJITSU LIMITED, Kawasaki-shi (JP)

(21) Appl. No.: 15/235,298

(22) Filed: Aug. 12, 2016

Related U.S. Application Data
(62) Division of application No. 14/098,632, filed on Dec. 6, 2013.

(30) Foreign Application Priority Data
Mar. 18, 2013 (JP) 2013-054818

(51) Int. Cl. H05K 7/20

(52) U.S. Cl. CPC H05K 7/20218; H05K 7/20145

(57) ABSTRACT

An electronic equipment includes a heat generating component, and a heat receiving device. The heat receiving device includes a case including a contacting surface which contacts the heat generating component, a flow passage, formed within the case, configured to flow a coolant flows, and an inflow port and an outflow port of the flow passage formed in an outer surface of the case. A distance from a spot having higher heat generation density than the other portions on a surface of the heat generating component which contacts the contacting surface to the inflow port is shorter than a distance from the spot to the outflow port.

### CROSS-REFERENCE TO RELATED APPLICATION

This application is a Divisional of co-pending application Ser. No. 14/098,632 filed on Dec. 6, 2013, which claims priority to Japanese Patent Application No. 2013-054818 filed on Mar. 18, 2013, the entire content of all of the above applications is hereby incorporated by reference.

### FIELD

Embodiments are related to an electronic equipment and a heat receiving device.

### BACKGROUND

A heat generating component is cooled by contacting with a heat receiving device inside which a flow passage through which a coolant is flowing is formed.

Japanese Patent Application Laid-Open No. 2007-324498 or Japanese Patent Application Laid-Open No. H5-160310 discloses related technologies.

### SUMMARY

According to an aspect of the embodiments, an electronic equipment includes: a heat generating component; and a heat receiving device, wherein the heat receiving device includes: a case including a contacting surface which contacts the heat generating component; a flow passage, formed within the case, configured to flow a coolant flows, and an inflow port and an outflow port of the flow passage formed in an outer surface of the case, and a distance from a spot having higher heat generation density than the other portions on a surface of the heat generating component which contacts the contacting surface to the inflow port is shorter than a distance from the spot to the outflow port.

The objects and advantages of the invention will be realized and attained by means of the elements and combinations particularly pointed out in the claims. It is to be understood that both the foregoing general description and the following detailed description are exemplary and explanatory, and are not restrictive of the invention, as claimed.

### BRIEF DESCRIPTION OF DRAWINGS

FIG. 1 illustrates an example of an electronic equipment.

FIG. 2 illustrates an example of a heat receiving device.

FIG. 3A and FIG. 3B illustrate an example heat receiving device.

FIG. 4A and FIG. 4B illustrate an example of a heat receiving device.

FIG. 5A and FIG. 5B illustrate an example of a heat receiving device.

FIG. 6A and FIG. 6B illustrate an example of a heat receiving device.

### DESCRIPTION OF EMBODIMENTS

The heat generating component has a temperature distribution. Therefore, the coolant receives heat from a spot where the heat generation density is not relatively high before the coolant reaches another spot where the heat generation density is high. Accordingly, when the coolant reaches the spot where the heat generation density is high, the temperature of the coolant may already have been increased. In this case, the spot where the heat generation density is high may not be efficiently cooled.

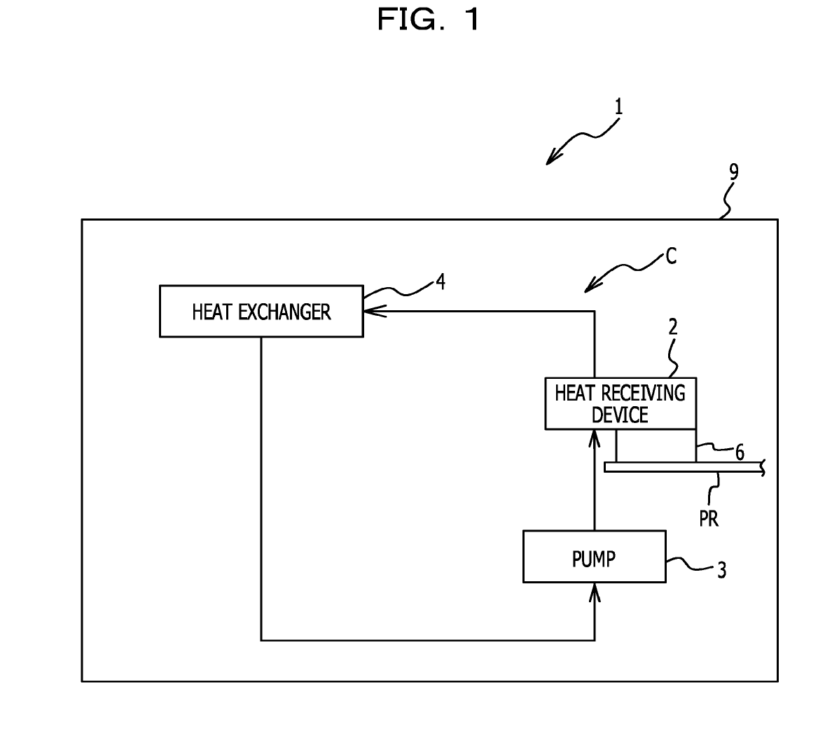

FIG. 1 illustrates an example of an electronic equipment. An electronic equipment 1 may be, for example, a supercomputer, a server, a network apparatus, a desktop computer, a notebook computer, or a tablet computer. Moreover, the electronic equipment 1 may be, for example, a monitor, a monitor equipped with a computer, a television, or an audio system. The electronic equipment 1 may include a cooling device C for cooling the heat generating component or a case 9 for accommodating the cooling device C.

The cooling device C includes a heat receiving device 2, a pump 3, a heat exchanger 4, a heat generating component 6, and a printed circuit board PR. The coolant circulates within the cooling device C. The heat receiving device 2 is arranged to contact with the heat generating component 6, and receives heat from the heat generating component 6 to transfer the heat to the coolant. The pump 3 circulates the coolant so that the coolant flows through the heat receiving device 2 and the heat exchanger 4 in this order. The heat exchanger 4 dissipates heat of the coolant to outside. The heat exchanger 4 may be any one of an air cooing type or a liquid cooing type heat exchanger. When the heat exchanger 4 is the air cooing type heat exchanger, a fan may be provided for cooling the heat exchanger 4. The respective devices are coupled with each other by a metal piping or a flexible hose. The propylene glycol based antifreeze fluid may be used as the coolant.

The heat generating component 6 may be an electronic component such as, for example, a LSI (Large-Scale Integration) or a CPU (Central Processing Unit). The heat generating component 6 may be a device in which a plurality of electronic components are equipped in a single package, or may be a single body semiconductor chip. The heat generating component 6 may also be an electronic component which generates heat with supplying of electrical power. The heat generating component 6 may be mounted on the printed circuit board PR.

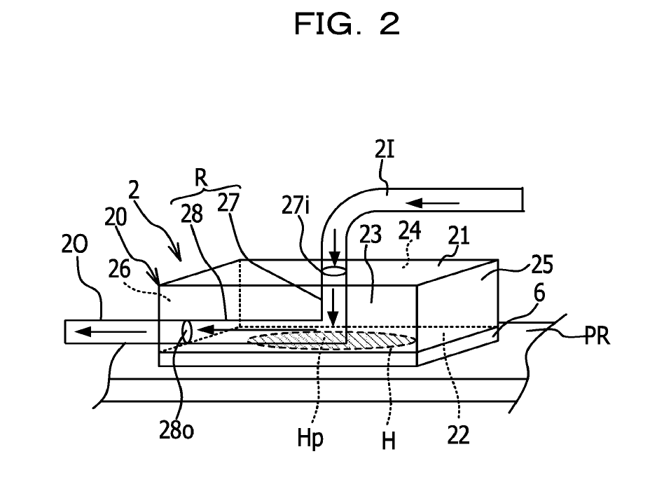

FIG. 2 illustrates an example of a heat receiving device. The heat receiving device 2 includes a case 20, an inflow pipe 21 and an outflow pipe 2O that are joined to the case 20. The case 20 may be made of aluminium or copper, and includes a top surface 21, a bottom surface 22, side surfaces 23, 24, 25 and 26. The top surface 21 and the bottom surface 22 are facing with each other, the side surface 23 and the side surface 24 are facing with each other, and the side surface 25 and the side surface 26 are facing with each other. The top surface 21 and the bottom surface 22 have the largest area. The bottom surface 22 is in contact with the top surface of the heat generating component 6. The bottom surface 22 may be an example of a contacting surface. The heat receiving device 2 may be a six-sided figure (e.g., a hexahedron) and also be, for example, a four-sided figure (e.g., a tetrahedron), a five-sided figure (e.g., a pentahedron), a seven-sided figure (e.g., a heptahedron) and a eight-sided figure (e.g., an octahedron).

A high-heat generation spot H having relatively higher heat generation density than other spots is indicated on the top surface of the heat generating component 6. The Hp which is the center of the high-heat generation spot H may be a spot having the highest heat generation density on the top surface of the heat generating component 6. In FIG. 2, the center Hp of the high-heat generation spot H approximately coincides with the center of the bottom surface 22, but is not limited thereto. In FIG. 2, the high-heat generation spot H is substantially circular, but is not limited to the circular shape. A shape, position or size of the high-heat generation spot may be different according to the type of the heat generating component. Plural high-heat generation spots may exist on the top surface of the heat generating component. For example, when the heat generating component 6 is a device in which a plurality of electronic components are equipped in a single package, a plurality of high-heat generation spots may be generated on the top surface of the heat generating component.

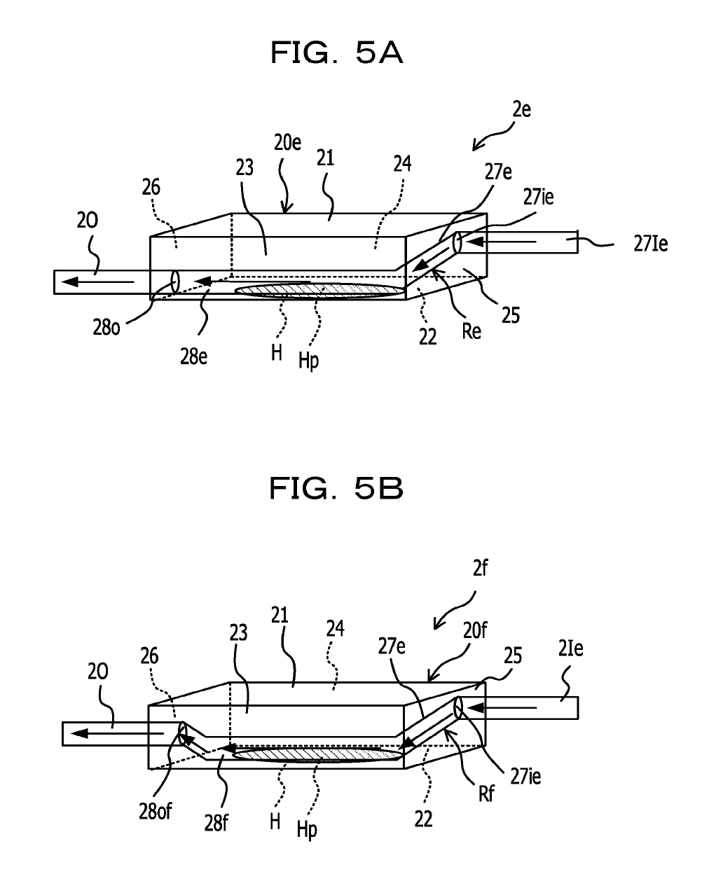

The inflow pipe 21 is joined to substantially the center of the top surface 21. The outflow pipe 2O is joined to the side surface 26 near to the bottom surface 22. The locations of the inflow pipe 21 and the outflow pipe 2O are set considering the intervention with, for example, hoses coupled to the pipes and other equipments arranged in the vicinity of the heat receiving device 2. The locations described herein may also be similarly adapted for the configurations in the FIG. 5A and FIG. 5B. The flow passage R through which the coolant flows is formed within the case 20. The flow passage R is communicated with the inflow pipe 21 and the outflow pipe 2O. The inflow pipe 21 and the outflow pipe 2O are coupled with the hoses, respectively, and as a result, the coolant is flown in or flown out through other apparatuses. The coolant flows in the inflow pipe 21, the flow passage R, and the outflow pipe 2O in this order.

The flow passage R includes an upstream part 27 and a downstream part 28 communicated with the upstream part 27 and positioned more at a downstream side than the upstream part 27. The upstream part 27 is shorter than the downstream part 28. The inflow port 27i communicated with the upstream part 27 is formed on the top surface 21. The outflow port 28o communicated with the downstream part 28 is formed on the side surface 26. The inflow pipe 21 and the outflow pipe 2O are coupled to the inflow port 27i and the outflow port 28o, respectively. The upstream part 27 extends substantially perpendicular to the top surface 21 and the bottom surface 22 from the top surface 21 toward the bottom surface 22. The downstream part 28 extends substantially in a straight line toward the side surface 26 along the bottom surface 22. The downstream part 28 is formed nearer to the bottom surface 22 than the top surface 21.

The upstream part 27 is spaced apart from the bottom surface 22 and the downstream part 28 is formed in the vicinity of the bottom surface 22. A distance spanning from the inflow port 27i to the center Hp of the high-heat generation spot H having the highest heat generation density is shorter than a distance spanning from the outflow port 28o to the center Hp of the high-heat generation spot H. For example, the inflow port 27i is formed in the vicinity of the center Hp of the high-heat generation spot H. Therefore, the coolant introduced from the case 20 may be guided to the center Hp by travelling a short distance and for a short time. A heat amount received from the heat generating component 6 until the coolant reaches the center Hp may be reduced as compared to a case where the coolant is introduced into the case 20 and travels a long distance to reach the center Hp. Therefore, the coolant is guided to the high-heat generation spot H before a temperature of the coolant increases to make it possible to cool the spot H preferentially than the other spots. A cooling efficiency of a spot having the higher heat generation density may be improved.

The downstream part 28 passes through the high-heat generation spot H, and is arranged in the vicinity of the bottom surface 22 and is longer than the upstream part 27. Accordingly, the coolant passing through the downstream part 28 may receive a large amount of heat from the heat generating component 6. Therefore, the heat generating component 6 may be efficiently cooled.

The outflow port 28o may be formed in any surface of the top surface 21 and the side surfaces 23-26 and the outflow pipe 2O may also be coupled in any surface of the top surface 21 and the side surfaces 23˜26.

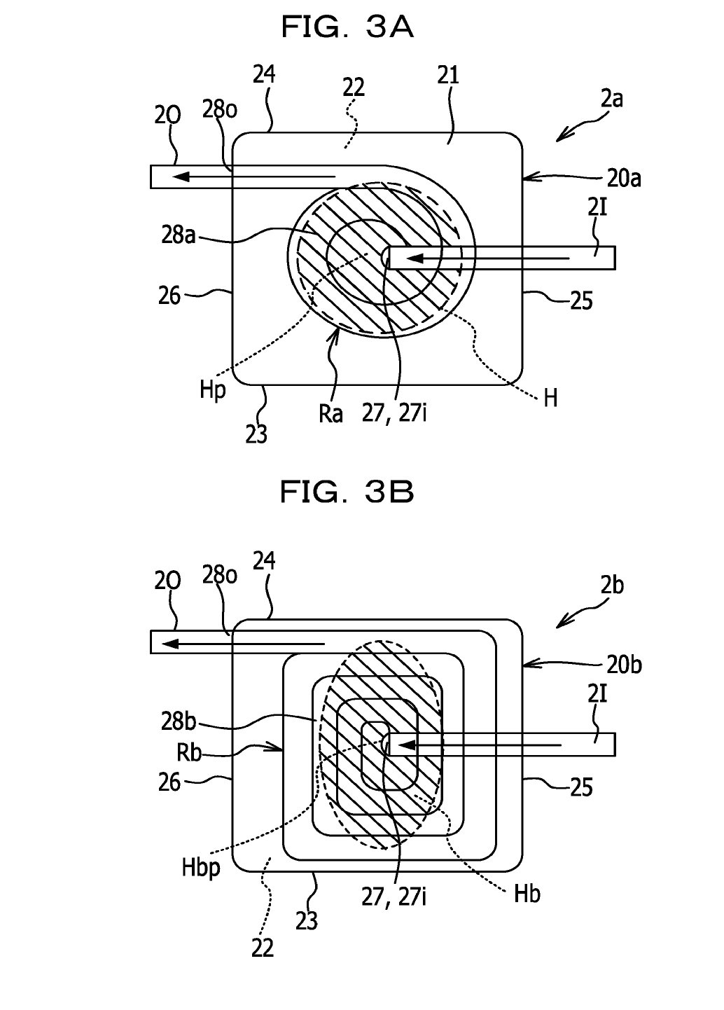

FIG. 3A and FIG. 3B illustrates an example of heat receiving device. In FIG. 3A and FIG. 3B, the same or similar reference numerals are given to substantially the same or similar reference elements as those illustrated in FIG. 2 and description thereof may be omitted or reduced. FIG. 3A illustrates the heat receiving device 2a when viewed from the top surface 21. The downstream part 28a of the flow passage Ra formed within the case 20a is formed in a spiral shape around a normal line perpendicular to the bottom surface 22. The downstream part 28a is formed in a convexed shape when viewed from a direction perpendicular to the bottom surface 22. The high-heat generation spot H may be circular. The downstream part 28a is formed in the spiral shape to pass through the high-heat generation spot H of the heat generating component described above and thus, the high-heat generation spot H of the heat generating component may be preferentially and efficiently cooled.

In the heat receiving device 2b illustrated in FIG. 3B, the downstream part 28b of the flow passage Rb formed within the case 20b is formed in a spiral shape similar to the downstream part 28a, but is formed with a plurality of straight line portions. For example, the downstream part 28b is formed in such a manner that the straight line portions are perpendicular to each other to continuously form a spiral shape in its entirety. The high-heat generation spot Hb may be an elliptical shape. A distance spanning from the inflow port 27i to the center Hp having the highest heat generation density of the high-heat generation spot Hb is shorter than a distance spanning from the outflow port 28o to center Hbp. The downstream part 28b is formed in the spiral shape to pass through the high-heat generation spot H of the heat generating component and thus, the high-heat generation spot H of the heat generating component may be preferentially and efficiently cooled.

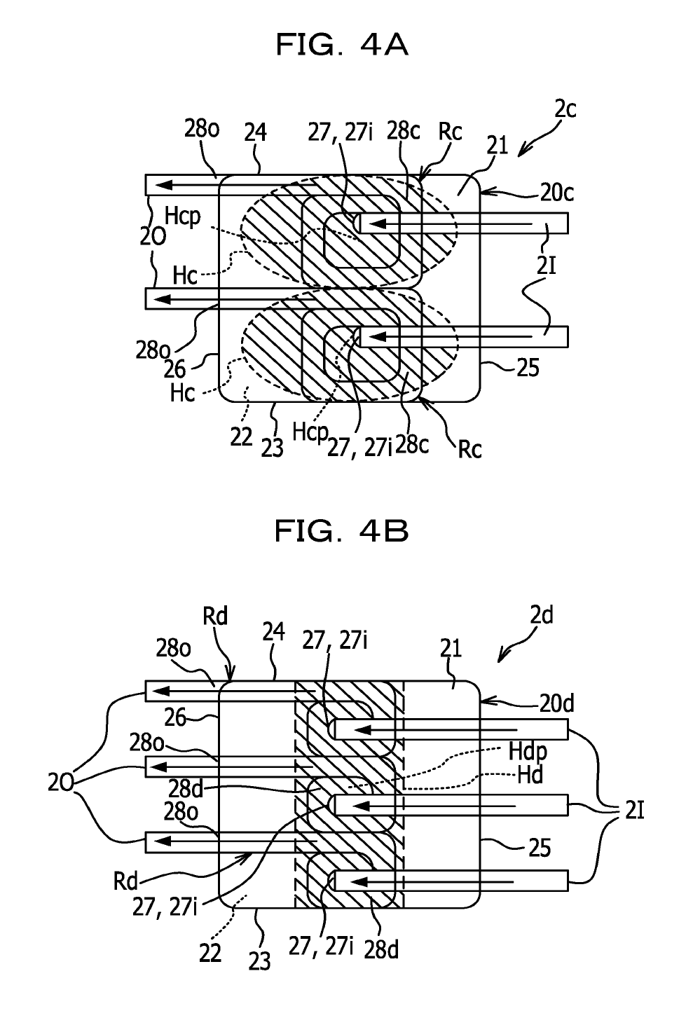

FIG. 4A and FIG. 4B illustrate an example of a heat receiving device. In FIG. 4A and FIG. 4B, the same or similar reference numerals are given to substantially the same or similar reference elements as those illustrated in FIG. 2 and description thereof may be omitted or reduced. Two flow passages Rc that do not converge with each other are formed within the case 20c in the heat receiving device 2c illustrated in FIG. 4A. Two high-heat generation spots Hc are formed on the heat generating component and, the centers Hcp of the high-heat generation spot Hc having the highest heat generation density are offset from the center of the bottom surface 22. Two flow passages Rc are arranged such that the centers Hcp of the two high-heat generation spots Hc on the heat generating component are corresponded to the inflow ports 27i. For example, the distance spanning from the center Hcp of the high-heat generation spot Hc to the inflow port 27i of one flow passage Rc is shorter than the distance spanning from the center Hcp to the outflow port 28o of the other flow passage. Each of two downstream parts 28c passes through two high-heat generation spots Hc, respectively. Therefore, two high-heat generation spots Hc of the heat generating component may be preferentially and efficiently cooled. The distance spanning from the center of the bottom surface 22 to the inflow port 27i of one flow passage Rc is also shorter than the distance spanning from the center of the bottom surface 22 to the outflow port 27o of one flow passage Rc.

Three flow passages Rd that do not converge with each other are formed within the case 20d in the heat receiving device 2d illustrated in FIG. 4B. The high-heat generation spot Hd is formed to be widened as if it is stretched in one direction with respect to the surface of the heat generating component. The center Hdp of the high-heat generation spot Hd having the highest heat generation density is offset from the center of the bottom surface 22. As described above, the inflow ports 27i of the plurality of the flow passages Rd are also arranged in one direction in parallel to be corresponded with the high-heat generation spot Hd extended in a direction. The plurality of the downstream parts 28d pass through the high-heat generation spot Hd. Therefore, the high-heat generation spot Hd may be preferentially and efficiently cooled. The distance spanning from the center Hdp to the inflow port 27i of the flow passage Rd arranged on the center is also shorter than the distance spanning from the center Hdp to the outflow port 27o of one flow passage Rd arranged on the center.

FIG. 5A and FIG. 5B illustrates an exemplary heat receiving device. In FIG. 5A and FIG. 5B, the same or similar reference numerals are given to substantially the same or similar reference elements as those illustrated in FIG. 2 and description thereof may be omitted or reduced. In the heat receiving device 2e illustrated in FIG. 5A, the inflow pipe 27Ie is coupled to the side surface 25 of the case 20e and the inflow port 27ie is also formed on the side surface 25. The inflow port 27ie is formed at a position spaced apart from the bottom surface 22 while the outflow port 28o is formed at a position located in the vicinity of the bottom surface 22. The upstream part 27e of the flow passage Re extends obliquely downward to the bottom surface 22 side towards the center of the bottom surface 22 or the center Hp of the high-heat generation spot H. The downstream part 28e passes through the center Hp of the high-heat generation spot H.

As described above, the upstream part 27e is formed at a position spaced apart from the bottom surface 22 and the downstream part 28e extends along the bottom surface 22. Therefore, the coolant flowing within the upstream part 27e becomes difficult to receive heat from the heat generating component, and the coolant which is cold may be guided toward the high-heat generation spot H.

In the heat receiving device 2f illustrated in FIG. 5B, most portions of the downstream part 28f of the flow passage Rf of the case 20f extend along the bottom surface 22, but extends obliquely upward to be spaced apart from the bottom surface 22 at a portion right ahead of the outflow port 28of. For example, the outflow port 28of is formed at a position spaced apart from the bottom surface 22 in order to reduce the intervention caused by the hoses coupled to the outflow pipe 2O or the outflow pipe 2O, with respect to, for example, other equipments arranged in the vicinity of the heat receiving device 2f. Therefore, the outflow pipe 2O or the outflow port 28of may not be formed in the vicinity of the bottom surface 22.

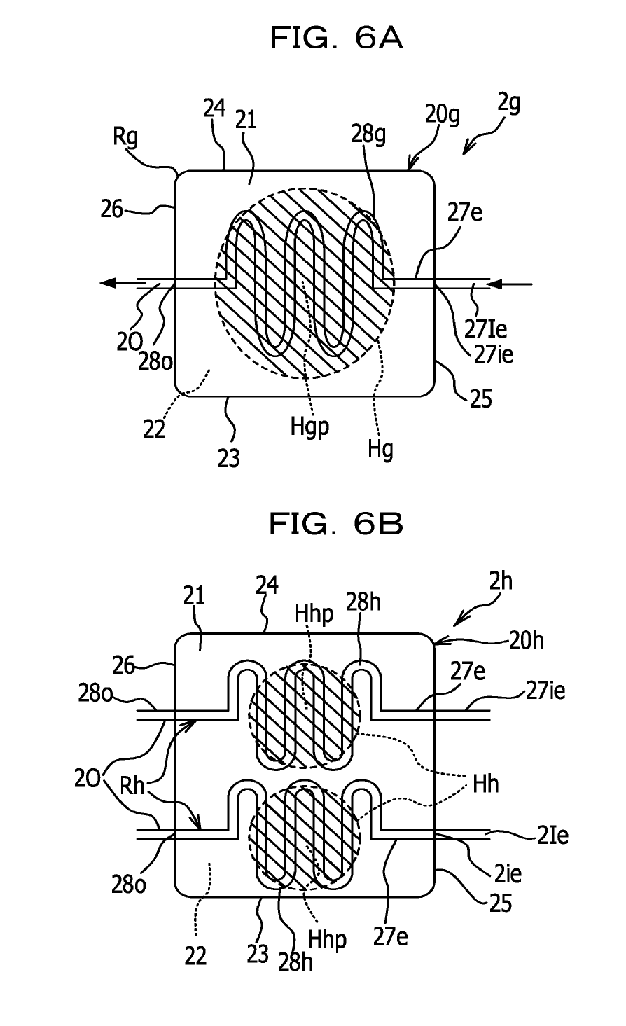

FIG. 6A and FIG. 6B illustrate an example of a heat receiving device. In FIG. 6A and FIG. 6B, the same or similar reference numerals are given to substantially the same or similar reference elements as those illustrated in FIG. 2 and description thereof may be omitted or reduced. In the heat receiving device 2g illustrated in FIG. 6A, the downstream part 28g of the flow passage Rg of the case 20g has a serpentine shape along the bottom surface 22 and passes through the high-heat generation spot Hg. Therefore, the high-heat generation spot Hg may be efficiently cooled while a length of the downstream part 28g is ensured around the high-heat generation spot H. As illustrated in FIG. 5A, the upstream part 27e extends obliquely downward toward the bottom surface 22 while maintaining a gap from the bottom surface 22 and thus, the high-heat generation spot H may be preferentially cooled. The downstream part 28g may pass through the center Hgp of the high-heat generation spot Hg or the vicinity of the center Hgp.

In the heat receiving device 2h illustrated in FIG. 6B, the two flow passages Rh are formed in the case 20h, and two downstream parts 28h are arranged at positions to pass through the two high-heat generation spots Hh of the heat generating component, respectively. Therefore, two high-heat generation spots Hh may be efficiently cooled. The upstream part 27e extends obliquely downward toward the bottom surface 22 while maintaining a gap from the bottom surface 22 and thus, the high-heat generation spot Hh may be preferentially cooled.

For example, as illustrated in FIG. 2, the downstream part may have a serpentine shape along the bottom surface 22 also in the heat receiving device in which the inflow port 27i is formed on the top surface 21. As illustrated in FIG. 5A, the downstream part may also have a spiral shape illustrated in FIG. 3A or FIG. 3B in the heat receiving device in which the inflow port 27ie is formed on the side surface. In this case, the upstream part may extend to the vicinity of the center of the bottom surface 22 in a direction parallel with the bottom surface 22 while maintaining a certain gap from the bottom surface 22 and extend to the bottom surface 22 side in the vicinity of the center, such that the downstream part may have a spiral shape.

For example, a single heat generating component may be cooled down by the plurality of the heat receiving devices. In this case, at least one of the plurality of the heat receiving devices may be the heat receiving device described above.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic equipment comprising:
a heat generating component; and
a heat receiving device,
wherein the heat receiving device comprises:
a case including a contacting surface which contacts the heat generating component;
a flow passage, formed within the case, configured to flow a coolant, and
an inflow port and an outflow port of the flow passage formed in an outer surface of the case, and
a distance from a spot having higher heat generation density than the other portions on a surface of the heat generating component which contacts the contacting surface to the inflow port is shorter than a distance from the spot to the outflow port.

2. The electronic equipment according to claim 1, wherein the downstream part has a serpentine shape along the contacting surface.

3. The electronic equipment according to claim 2, wherein the flow passage includes a plurality of sub-flow passages that do not converge with each other, and
each sub-downstream part of the plurality of the sub-flow passages has a serpentine shape along the contacting surface.

4. The electronic equipment according to claim 1, wherein the downstream part has a spiral shape around a normal line perpendicular to the contacting surface,
wherein the flow passage includes a plurality of sub-flow passages that do not converge with each other, and
respective sub-downstream parts of the plurality of the sub-flow passages have a spiral shape and are adjacent to each other.

5. The electronic equipment according to claim 1, wherein the flow passage includes a plurality of sub-flow passages that do not converge with each other.

6. An electronic equipment comprising:
a heat generating component; and
a heat receiving device,
wherein the heat receiving device comprises:
a case including a contacting surface which contacts the heat generating component; and
a flow passage, formed within the case, configured to flow a coolant,
the flow passage includes an upstream part spaced apart from the contacting surface and a downstream part located nearer to the contacting surface than the upstream part in a downstream side,
the upstream part extends in a direction other than the direction perpendicular to the contacting surface and extends towards a central spot of the contacting surface or another spot having higher heat generation density than the other portions on the surface of the heat generating component which contacts the contacting surface.

7. The electronic equipment according to claim 6, wherein the downstream part has a serpentine shape along the contacting surface.

8. The electronic equipment according to claim 7, wherein the flow passage includes a plurality of sub-flow passages that do not converge with each other, and
each sub-downstream part of the plurality of the sub-flow passages has a serpentine shape along the contacting surface.

9. The electronic equipment according to claim 6, wherein the downstream part has a spiral shape around a normal line perpendicular to the contacting surface,
wherein the flow passage includes a plurality of sub-flow passages that do not converge with each other, and
respective sub-downstream parts of the plurality of the sub-flow passages have a spiral shape and are adjacent to each other.

10. The electronic equipment according to claim 6, wherein the flow passage includes a plurality of sub-flow passages that do not converge with each other.

11. A heat receiving device comprising:
a case provided with a bottom surface; and
a flow passage formed within the case,
wherein the flow passage includes an upstream part spaced apart from the bottom surface and a downstream part located nearer to the bottom surface than the upstream part in a downstream side,
wherein the flow passage includes a plurality of sub-flow passages that do not converge with each other, each sub-downstream part of the plurality of the flow passages has a serpentine shape, and
wherein the upstream part extends in a direction other than the direction perpendicular to the bottom surface and extends towards the center of the bottom surface.

12. A heat receiving device comprising:
a case provided with a bottom surface;
a flow passage formed within the case; and
an inflow port and an outflow port of the flow passage formed in an outer surface of the case, and
wherein the flow passage includes a plurality of sub-flow passages that do not converge with each other, and
wherein a distance from a center of the bottom surface to the inflow port of at least one of the plurality of the sub-flow passages is shorter than a distance from the center to the outflow port of the at least one of the plurality of the sub-flow passages.

13. The heat receiving device according to claim 14, wherein the respective downstream parts of the plurality of the sub-flow passages have a spiral shape around a normal line perpendicular to the contacting surface and the portions of the sub-flow passages forming the spiral shape are adjacent to each other.
